(19) United States
(12) Patent Application Publication
(10) Pub. No.: US 2015/0263700 A1
(43) Pub. Date: Sep. 17, 2015

(54) SEMICONDUCTOR DEVICE

(71) Applicant: KABUSHIKI KAISHA TOSHIBA, Tokyo (JP)

(72) Inventors: Takaaki YASUMOTO, Kawasaki Kanagawa (JP); Naoko YANASE, Inagi Tokyo (JP); Kazuhide ABE, Kawasaki Kanagawa (JP); Takeshi UCHIHARA, Kawaguchi Saitama (JP); Yasunobu SAITO, Nomi Ishikawa (JP); Toshiyuki NAKA, Nonoichi Ishikawa (JP); Akira YOSHIOKA, Nomi Ishikawa (JP); Tasuku ONO, Nonoichi Ishikawa (JP); Tetsuya OHNO, Nomi Ishikawa (JP); Hidetoshi FUJIMOTO, Kawasaki Kanagawa (JP); Shingo MASUKO, Kanazawa Ishikawa (JP); Masaru FURUKAWA, Himeji Hyogo (JP); Yasunari YAGI, Ibo Hyogo (JP); Miki YUMOTO, Kawasaki Kanagawa (JP); Atsuko IIDA, Yokohama Kanagawa (JP); Yukako MURAKAMI, Chigasaki Kanagawa (JP); Yoshikazu SUZUKI, Komatsu Ishikawa (JP)

(21) Appl. No.: 14/475,524

(22) Filed: Sep. 2, 2014

(30) Foreign Application Priority Data
Mar. 14, 2014 (JP) 2014-052751

(51) Int. Cl. H03H 9/64; H01L 29/205; H01L 49/02; H01L 29/778; H01L 29/78; H01L 29/20; H01L 27/07

(52) U.S. Cl. CPC H03H 9/6406; H01L 29/2003; H01L 29/205; H01L 27/0705; H01L 27/0727; H01L 29/7787; H01L 29/78; H01L 28/20

(57) ABSTRACT

According to one embodiment, a semiconductor device includes a GaN-based semiconductor layer, a resonator that uses a first portion of the GaN-based semiconductor layer as a piezoelectric layer to resonate, and a transistor that uses a second portion of the GaN-based semiconductor layer as a channel layer.

### CROSS-REFERENCE TO RELATED APPLICATION

This application is based upon and claims the benefit of priority from Japanese Patent Application No. 2014-052751, filed Mar. 14, 2014, the entire contents of which are incorporated herein by reference.

### FIELD

Embodiments described herein relate generally to a semiconductor device.

### BACKGROUND

GaN-based semiconductor devices are expected to be used in a variety of systems such as semiconductor devices for power electronics and high-frequency power semiconductor devices. In order to reduce the sizes of systems using GaN-based semiconductor devices, it would be desirable to reduce the sizes of the GaN-based semiconductor devices.

### DESCRIPTION OF THE DRAWINGS

FIG. 1 is a cross-sectional view schematically illustrating a semiconductor device according to a first embodiment.

FIG. 2 is a circuit diagram illustrating the semiconductor device according to the first embodiment.

FIG. 3 is a plan view schematically illustrating the structure of a resonator according to the first embodiment.

FIG. 4 is a cross-sectional view schematically illustrating a semiconductor device according to a second embodiment.

FIG. 5 is a plan view schematically illustrating a semiconductor device according to a third embodiment.

FIG. 6 is a cross-sectional view schematically illustrating the semiconductor device according to the third embodiment.

### DETAILED DESCRIPTION

An embodiment of the present disclosure provides semiconductor device having a resonator including a GaN-based semiconductor layer.

In general, according to one embodiment, a semiconductor device includes a GaN-based semiconductor layer, wherein a first portion of the GaN-based semiconductor is a piezoelectric layer of a resonator, and a second portion of the GaN-based semiconductor layer is a channel layer of a transistor.

Hereinafter, embodiments of the present disclosure will be described with reference to the accompanying drawings. In the following description, the same reference symbols will be used for identical or substantially similar elements, and if an element is described once, the element may not be repeatedly described in different embodiments.

In this specification, the term “GaN-based semiconductor” is the general term for semiconductors having a composition including gallium nitride (GaN), aluminum nitride (AlN), or indium nitride (InN), or an intermediate composition of these materials. Also, in this specification, the term “AlGaN” means a semiconductor represented by a formula of AlₓGa₁₋ₓN (wherein 0<x<1).

### First Embodiment

A semiconductor device according to the first embodiment includes a GaN-based semiconductor layer, a resonator (resonator element) that uses a first portion of the GaN-based semiconductor layer as a piezoelectric layer for resonating, and a transistor (transistor element) that uses a second portion of the GaN-based semiconductor layer as a channel layer. More specifically, the semiconductor device includes the GaN-based semiconductor layer, a resonator element that uses a first portion of the GaN-based semiconductor layer as a piezoelectric layer, an inverter that includes a transistor element which uses a second portion of the GaN-based semiconductor layer as a channel layer, and a resistor. In the semiconductor device, the resonator element is connected in parallel with the inverter and the resistor.

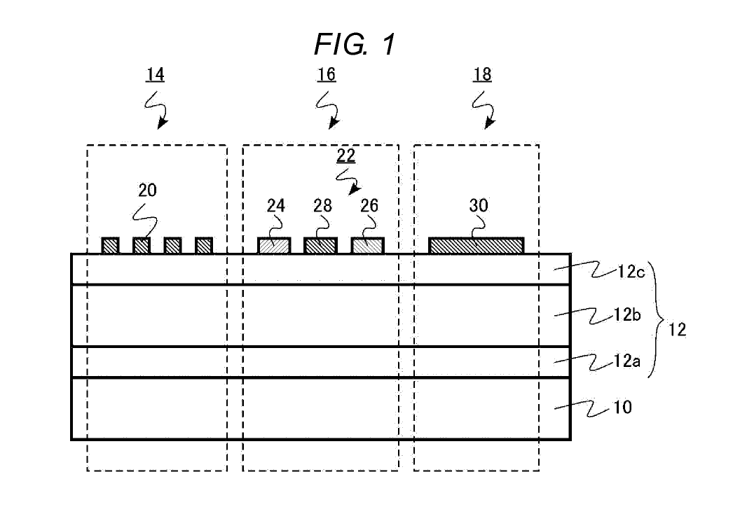

FIG. 1 is a cross-sectional view schematically illustrating the semiconductor device according to the first embodiment. The semiconductor device in this first embodiment is an oscillation circuit using a GaN-based semiconductor, for example.

As depicted in FIG. 1, the first embodiment includes a substrate 10, a GaN-based semiconductor layer 12, a resonator 14, an inverter 16, and a resistor 18. The substrate 10 is made of, for example, GaN; however, the substrate 10 may be made of another material, such as gallium oxide, SiC, Si, or sapphire, other than GaN.

On the substrate 10, the GaN-based semiconductor layer 12 is provided. The GaN-based semiconductor layer 12 includes a buffer layer 12a, a GaN layer 12b, and an AlGaN layer 12c provided sequentially from the substrate 10. Thus, here the GaN-based semiconductor layer 12 has a laminate structure comprising the buffer layer 12a, the GaN layer 12b, and the AlGaN layer 12c stacked in sequence.

The surface of the GaN-based semiconductor layer 12 has, for example, an angle that is equal to or greater than 0 degree and equal to or less than 1 degree with respect to a c-plane. It is possible to approximate the crystal structure of a GaN-based semiconductor to a hexagonal system. Thus, a surface of a hexagonal prism having a c-axis along the axial direction as a normal line (the top surface of the hexagonal prism) is the c-plane, that is, (0001) plane.

In order for the resonator 14 to have an excellent resonance characteristic, it is preferable that the surface of the GaN-based semiconductor layer 12 should have an angle that is equal to or greater than 0 and equal to or less than 1 degree with respect to the c-plane (in a range of between 0 degrees and 1 degree, inclusive). It is even more preferable that the surface of the GaN-based semiconductor layer 12 should have an angle that is equal to or greater than 0 degree and equal to or less than 0.3 degrees or less with respect to the c-plane.

The buffer layer 12a has a function of relieving lattice mismatch between the substrate 10 and the GaN-based semiconductor layer 12. The buffer layer 12a is formed of, for example, a multi-layer structure of AlGaN and GaN. For the AlGaN layer 12c, for example, a semiconductor represented by a composition formula of AlₓGa₁₋ₓN (wherein 0<x<0.3) is used.

The resonator 14 has an inter-digitated transducer (IDT) 20 provided on the AlGaN layer 12c. The IDT 20 is made of a conductor such as a metal. For example, the IDT 20 is made of a metal containing aluminum (Al) as a main component. The resonator 14 uses the AlGaN layer 12c as a piezoelectric layer.

The inverter 16 includes a transistor 22. The transistor 22 is, for example, a high electron mobility transistor (HEMT).

When the transistor 22 is an HEMT, the GaN layer 12b and the AlGaN layer 12c are used as a so-called operation layer (a channel layer) and a so-called barrier layer (an electron supply layer), respectively. The transistor 22 in this embodiment includes a source electrode 24, a drain electrode 26, and a gate electrode 28.

The source electrode 24, the drain electrode 26, and the gate electrode 28 are made of a conductor such as a metal. For example, the source electrode 24, the drain electrode 26, and the gate electrode 28 are made of a metal containing aluminum (Al) as a main component. It is typically preferable that the source electrode 24 and the drain electrode 26 should be in ohmic contact with the GaN-based semiconductor layer 12.

In order to facilitate manufacturing, it is typically preferable that the IDT 20 and the gate electrode 28 should be formed of the same material.

The resistor 18 includes a resistive layer 30 as a resistor disposed on the AlGaN layer 12c. The resistive layer 30 is made of a conductor such as a metal or a semiconductor. For example, the resistive layer 30 is a polycrystalline silicon layer. In some embodiments, the resistor 18 may be formed of an impurity layer provided within the GaN-based semiconductor layer 12 rather than being formed on an upper surface of layer 12c.

It also is possible to provide element isolation regions (though these are not specifically depicted in FIG. 1) between the resonator 14, the inverter 16, and the resistor 18. The element isolation regions are formed of an insulator such as a silicon oxide film. The element isolation regions can also be formed, for example, by introducing an impurity into the GaN-based semiconductor layer 12. Alternatively, the element isolation regions may have a mesa structure, that is, a physical gap or contour formed in the GaN-based semiconductor layer can be used to separate/isolate the various elements. Also, the element isolation regions may be formed by patterning an insulator on the surface of the GaN-based semiconductor layer 12.

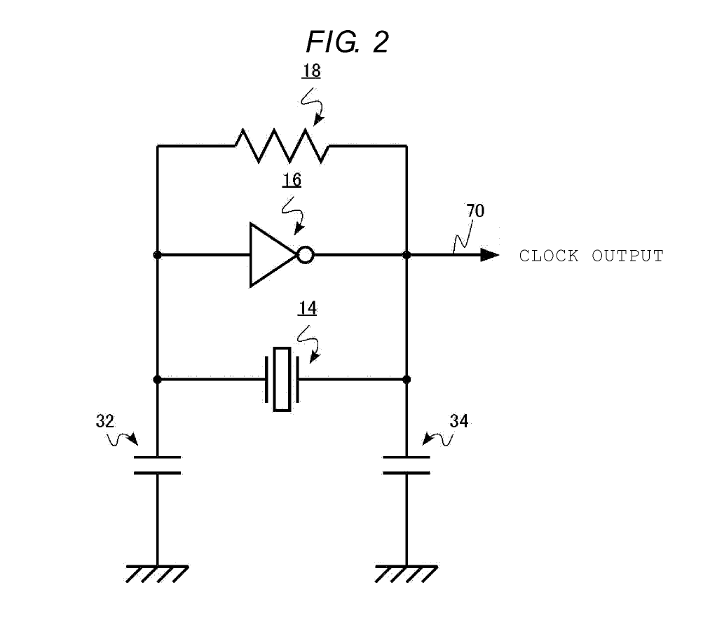

FIG. 2 is a circuit diagram illustrating the semiconductor device according to the first embodiment. The semiconductor device according to the first embodiment is an oscillation circuit.

The resonator 14, the inverter 16, and the resistor 18 are connected in parallel. A first end of the resonator 14 is connected to a first capacitor 32 and a second end of the resonator 13 is connected to a second capacitor 34. The first capacitor 32 is connected between resonator 14 and a ground potential. The second capacitor 34 is connected between the resonator 14 and a ground potential.

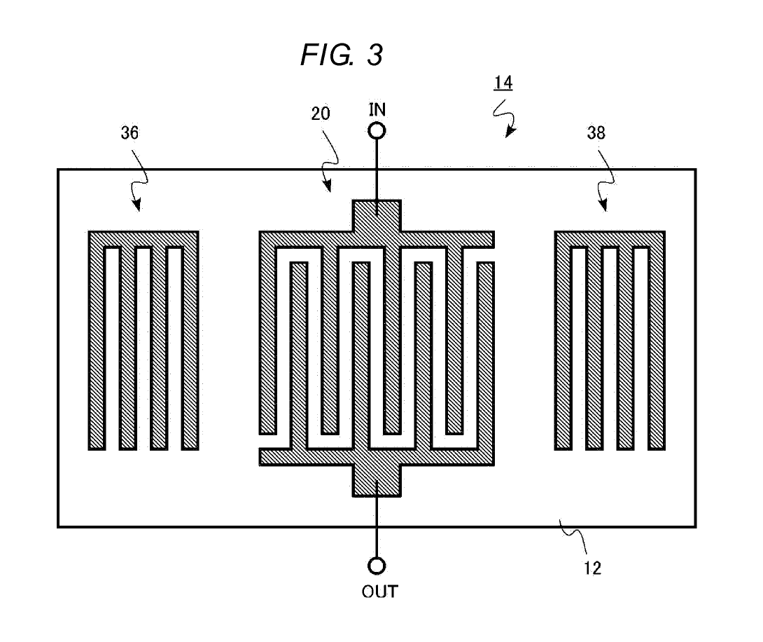

FIG. 3 is a plan view schematically illustrating the structure of the resonator 14 according to the first embodiment. The resonator 14 includes the IDT 20, a first grating 36, and a second grating 38. Each of these elements is provided on the GaN-based semiconductor layer 12. The IDT 20 is between the first grating 36 and the second grating 38 in a direction parallel to an upper surface of the GaN-based semiconductor layer 12.

Here, the resonator 14 uses a surface acoustic wave (SAW). The GaN-based semiconductor layer 12 is formed of a piezoelectric material. If an electric field is applied from the outside, the piezoelectric material is distorted. For this reason, if an AC voltage is applied between an IN terminal and an OUT terminal of the IDT 20, an SAW is generated at the surface of the GaN-based semiconductor layer 12.

The SAW generated by the IDT 20 is reflected by the first grating 36 and the second grating 38. Therefore, it is possible to produce a resonance effect. The resonator 14 shown in FIG. 3 is a so-called “one-port” resonator having one IDT 20. However, it is also possible to provide a so-called “two-port” resonator having two IDTs 20.

The inverter 16 functions as an amplifying circuit. In the first embodiment, the inverter 16 is configured using an HEMT as a transistor. For example, the inverter 16 may be configured using an HEMT and a resistive element (not specifically depicted).

The resistor 18 functions as a feedback resistor. Also, the first capacitor 32 and the second capacitor 34 have load capacitance. According to the oscillation circuit shown in FIG. 2, it is possible to output a signal having a desired frequency from an output terminal 70 as a clock output.

In the oscillation circuit according to the first embodiment, the resonator 14 and the inverter 16 are formed using the same GaN-based semiconductor layer 12. Therefore, it is unnecessary to form an external resonator (such as a crystal resonator), separately from a semiconductor chip including other device components, such as the inverter 16. Therefore, it is possible to implement a one-chip oscillation circuit, which is capable of being decreased in size by relatively simple manufacturing methods. Also, the resonator structure provided by the first embodiment has higher resistance against oscillation or shock than an external crystal resonator or the like. Thus, it is possible to implement an oscillation circuit having a higher resistance to environmental shocks or vibrations.

### Second Embodiment

A semiconductor device according to the second embodiment is substantially similar to the first embodiment excepting that the transistor configuring the inverter is not an HEMT, but a metal insulator semiconductor field effect transistor (MISFET).

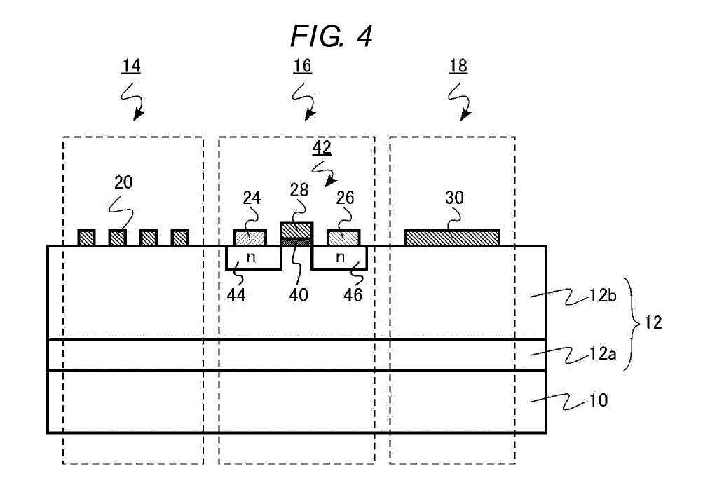

FIG. 4 is a cross-sectional view schematically illustrating the semiconductor device according to the present embodiment. In the second embodiment, the GaN-based semiconductor layer 12 includes the buffer layer 12a and the GaN layer 12b provided sequentially from the substrate 10.

The surface of the GaN-based semiconductor layer 12 is the GaN layer 12b rather than the AlGaN layer 12c (which is not required in the second embodiment).

The surface of the GaN-based semiconductor layer 12 has, for example, an angle that is equal to or greater than 0 degree and equal to or less than 1 degree with respect to the c-plane.

The inverter 16 has a transistor 42. The transistor 42 is an n-type MISFET using electrons as carriers.

The transistor 42 uses the GaN layer 12b as a so-called operation layer (a channel layer). Also, the transistor 42 includes a source electrode 24, a drain electrode 26, and a gate electrode 28. Between the gate electrode 28 and the GaN layer 12b, a gate insulating film 40 is provided. The gate insulating film 40 is, for example, a silicon oxide film.

Also, in the GaN layer 12b, an n-type source region 44 and an n-type drain region 46 are provided. The n-type source region 44 and the n-type drain region 46 contain, for example, silicon (Si) as an n-type impurity.

For example, the inverter 16 according to the second embodiment is configured using an n-type MISFET and a resistive element (not specifically depicted). The inverter 16 may also be, for example, a CMOS inverter using an n-type MISFET and a p-type MOSFET. If a CMOS inverter is used, it is possible to reduce overall power consumption of the device.

Similarly to the first embodiment, it is possible to implement a one-chip oscillation circuit. Also, it is possible to implement an oscillation circuit having high resistance to environmental shock or vibrations.

### Third Embodiment

A semiconductor device according to the third embodiment includes: a GaN-based semiconductor layer; a high-breakdown-voltage circuit that includes a first transistor using a first portion of the GaN-based semiconductor layer as a channel layer; a control circuit that includes a second transistor using a second portion of the GaN-based semiconductor layer as a channel layer and having a lower breakdown voltage between the source and the drain than that of the first transistor, and that controls the high-breakdown-voltage circuit, and an oscillation circuit that includes a resonator that uses a third portion of the GaN-based semiconductor layer as a piezoelectric layer to resonate, an inverter that includes a third transistor using a fourth portion of the GaN-based semiconductor layer as a channel layer and having a lower breakdown voltage between the source and the drain than that of the first transistor, and is connected in parallel to the resonator, and a resistor which is connected in parallel to the inverter.

The semiconductor device according to the third embodiment includes the high-breakdown-voltage circuit having a power device, a control circuit for the power device, and an oscillation circuit, for generating a clock signal for the control circuit, on the GaN-based semiconductor layer. In the semiconductor device according to the third embodiment, the oscillation circuit can be the same as the oscillation circuit according to the first embodiment.

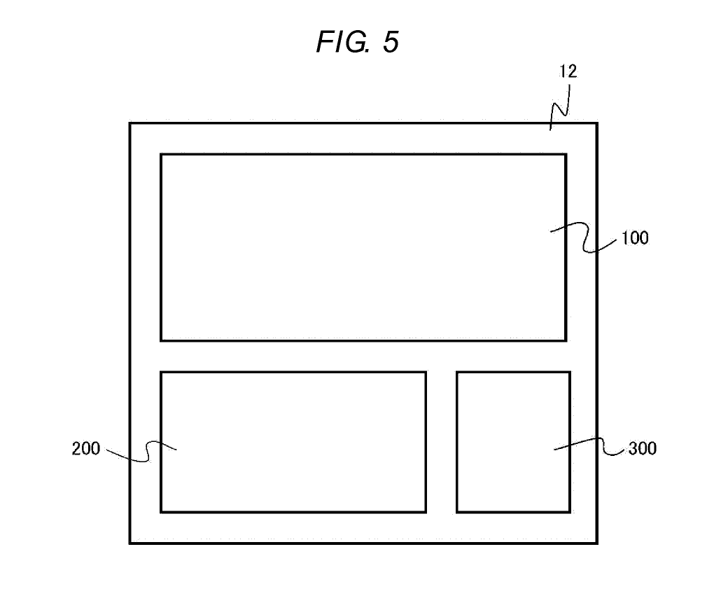

FIG. 5 is a plan view schematically illustrating the semiconductor device according to the third embodiment. The semiconductor device according to the third embodiment is a so-called intelligent power device having a high-breakdown-voltage circuit 100, a control circuit 200, and an oscillation circuit 300 on the same GaN-based semiconductor layer 12.

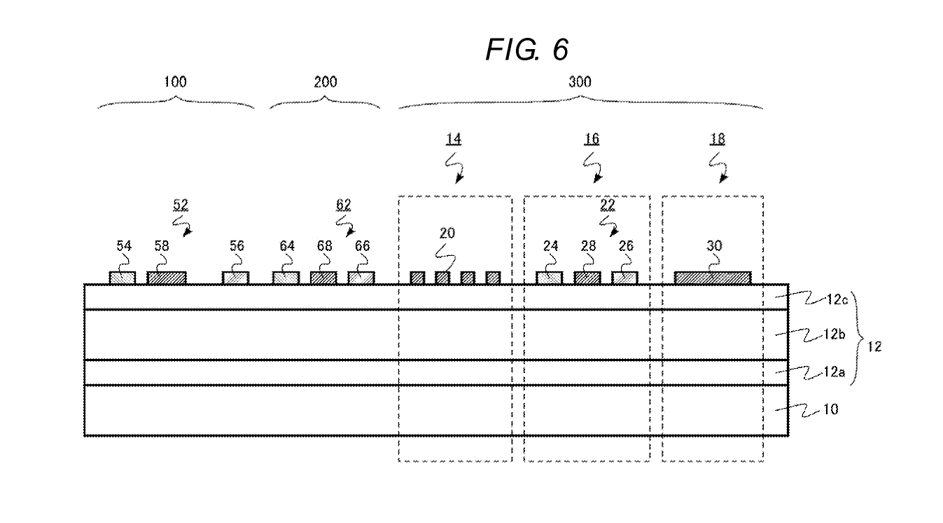

FIG. 6 is a cross-sectional view schematically illustrating the semiconductor device according to the third embodiment. Also, FIG. 6 is a conceptual view for purposes of explanation, and does not necessarily illustrate a specific cross section of FIG. 5.

The high-breakdown-voltage circuit 100 includes a power transistor (a first transistor) 52. The power transistor 52 is, for example, an HEMT using the GaN layer 12b and the AlGaN layer 12c as a so-called operation layer (a channel layer) and a so-called barrier layer (an electron supply layer), respectively. Also, the power transistor 52 includes a source electrode 54, a drain electrode 56, and a gate electrode 58.

The control circuit 200 includes a transistor (a second transistor) 62. The transistor 62 is, for example, an HEMT using the GaN layer 12b and the AlGaN layer 12c as a so-called operation layer (a channel layer) and a so-called barrier layer (an electron supply layer), respectively. The breakdown voltage between the source and the drain of the transistor 62 is lower than the breakdown voltage between the source and drain of the power transistor 52. Also, the distance between the gate electrode and the drain electrode of the transistor 62 is shorter than the distance between the gate electrode and the drain electrode of the power transistor 52.

The control circuit 200 has a function of controlling the high-breakdown-voltage circuit 100. The control circuit 200 may also have a function of protecting the high-breakdown-voltage circuit 100.

The oscillation circuit 300 includes the resonator 14, the inverter 16, and the resistor 18. The resonator 14 uses the AlGaN layer 12c as a piezoelectric layer. Also, the inverter 16 includes a transistor (a third transistor) 22. The oscillation circuit 300 generates a clock signal for driving the control circuit 200.

The transistor 22 uses the GaN layer 12b and the AlGaN layer 12c as a so-called operation layer (a channel layer) and a so-called barrier layer (an electron supply layer), respectively. Also, the transistor 22 has the source electrode 24, the drain electrode 26, and the gate electrode 28. The breakdown voltage between the source and the drain of the transistor 22 is lower than the breakdown voltage between the source and drain of the power transistor 52. Also, the distance between the gate electrode and the drain electrode of the transistor 22 is shorter than the distance between the gate electrode and the drain electrode of the power transistor 52.

According to the third embodiment, the same GaN-based semiconductor layer 12 is used to provide the high-breakdown-voltage circuit 100, the control circuit 200, and the oscillation circuit 300. Therefore, it is unnecessary to form a crystal resonator and/or an oscillation circuit, or the like for supplying a clock signal to the control circuit separately from the semiconductor chip including the high-breakdown-voltage circuit 100 and the control circuit 200. Therefore, it is possible to implement an intelligent power device capable of being decreased in size by a relatively simple manufacturing method. Also, since a GaN-based semiconductor material having high environmental durability is used, it is possible to implement an intelligent power device having high environmental durability.

In the embodiments, a case where the GaN-based semiconductor layer includes a GaN layer or has a laminate structure of a GaN layer and an AlGaN layer has been mainly described. However, as the GaN-based semiconductor layer, a GaN-based semiconductor having any other composition, or any other laminate structure, may be applied.

Also, in the embodiments, a case of forming a power device and an oscillation circuit by using the same GaN-based semiconductor layer has been described as an example. However, it is possible to use the same GaN-based semiconductor layer to form an oscillation circuit and other devices such as a high-frequency device for communication or a micro processing unit (MPU).

Also, in the embodiments, a case of using a resonator in an oscillation circuit has been described as an example. However, it is possible to use a resonator structure as a filter.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a GaN-based semiconductor layer, wherein
a first portion of the GaN-based semiconductor is a piezoelectric layer of a resonator, and
a second portion of the GaN-based semiconductor layer is a channel layer of a transistor.

2. The semiconductor device according to claim 1, wherein the resonator includes an inter-digitated transducer on the GaN-based semiconductor layer.

3. The semiconductor device according to claim 2, wherein the transistor includes a gate electrode, and
the gate electrode and the inter-digitated transducer are comprised of a same material.

4. The semiconductor device according to claim 1, wherein a surface of the GaN-based semiconductor layer has an angle, with respect to a c-plane of the GaN-based semiconductor layer, that is within a range of between 0 degree and 1 degree, inclusive.

5. The semiconductor device according to claim 1, wherein the transistor is a high electron mobility transistor (HEMT).

6. The semiconductor device according to claim 1, wherein the transistor is a metal-insulator-semiconductor field effect transistor (MISFET).

7. The semiconductor device according to claim 1, wherein the GaN-based semiconductor layer comprises a GaN layer and an AlGaN layer,
the first portion of the GaN-based semiconductor layer is the AlGaN layer, and
the second portion of the GaN-based semiconductor layer is the GaN layer.

8. A semiconductor device, comprising:
a resonator, an inverter, and a resistor connected in parallel, the inverter including a transistor;
a GaN-based semiconductor layer, wherein
a first portion of the GaN-based semiconductor layer is a piezoelectric layer of the resonator, and
a second portion of the GaN-based semiconductor layer is a channel layer of the transistor.

9. The semiconductor device according to claim 8, wherein the resonator includes an inter-digitated transducer on the GaN-based semiconductor layer.

10. The semiconductor device according to claim 9, wherein the transistor includes a gate electrode, and
the gate electrode and the inter-digitated transducer are comprised of a same material.

11. The semiconductor device according to claim 8, wherein a surface of the GaN-based semiconductor layer has an angle, with respect to a c-plane of the GaN-based semiconductor layer, that is within a range of between 0 degrees and 1 degree, inclusive.

12. The semiconductor device according to claim 8, wherein
the GaN-based semiconductor layer comprises a GaN layer and an AlGaN layer,
the first portion of the GaN-based semiconductor layer is the AlGaN layer, and
the second portion of the GaN-based layer is the GaN layer.

13. The semiconductor device according to claim 8, wherein the inverter is a CMOS inverter.

14. The semiconductor device according to claim 8, wherein the resistor includes a polycrystalline silicon layer on the GaN-based semiconductor layer.

15. The semiconductor device according to claim 8, wherein the transistor is a high electron mobility transistor (HEMT).

16. The semiconductor device according to claim 8, wherein the transistor is a metal-insulator-semiconductor field effect transistor (MISFET).

17. A semiconductor device, comprising:
a GaN-based semiconductor layer;
a high-breakdown-voltage circuit that includes a first transistor, a first portion of the GaN-based semiconductor layer being a channel layer of the first transistor;
a control circuit configured to control the high-breakdown-voltage circuit and including a second transistor, a second portion of the GaN-based semiconductor layer being a channel layer of the second transistor, the second transistor having a breakdown voltage that is lower than a breakdown voltage of the first transistor; and
an oscillation circuit that includes a resonator, an inverter, and a resistor connected in parallel, a third portion of the GaN-based semiconductor layer being a piezoelectric layer of the resonator, the inverter including a third transistor, a fourth portion of the GaN-based semiconductor layer being a channel layer of the third transistor.

18. The semiconductor device according to claim 17, wherein the first transistor is a high electron mobility transistor (HEMI).

19. The semiconductor device according to claim 17, wherein the resonator includes an inter-digitated transducer on the GaN-based semiconductor layer.

20. The semiconductor device according to claim 19, wherein the third transistor includes a gate electrode, and the gate electrode and the inter-digitated transducer are comprised of a same material.
